(19) United States
(12) Patent Application Publication
(10) Pub. No.: US 2018/0156403 A1
(43) Pub. Date: Jun. 7, 2018

(54) THERMOELECTRIC LAMP

(71) Applicant: Alan Millan, Delray Beach, FL (US)

(72) Inventor: Alan Millan, Delray Beach, FL (US)

(21) Appl. No.: 15/830,761

(22) Filed: Dec. 4, 2017

Related U.S. Application Data
(60) Provisional application No. 62/429,239, filed on Dec. 2, 2016.

(51) Int. Cl. F21S 9/04; F21V 14/04; F21V 14/02; H01L 35/28

(52) U.S. Cl. CPC F21S 9/04; F21V 14/04; F21Y 2115/10; H01L 35/28; F21V 14/02

(57) ABSTRACT

A thermoelectric lamp for illuminating a space. The thermoelectric lamp comprises a first housing and a second housing. The first housing includes a panel and a sidewall forming an interior volume having an open lower end. A light source is disposed on a first surface of the panel, wherein the light source is operably connected to a motor affixed within the interior volume of the first housing. A thermoelectric generator is operably connected to the motor and disposed at the open lower end of the first housing. The second housing comprises a base and a sidewall forming an interior volume having an open upper end, wherein the open upper end removably secures to the lower open end of the first housing. The second housing includes an opening that receives a candle therethrough, wherein the thermoelectric generator coverts heat generated from the candle into electrical energy that powers the light source.

### CROSS REFERENCE TO RELATED APPLICATION

This application claims the benefit of U.S. Provisional Application No. 62/429,239 filed on Dec. 2, 2016. The above identified patent application is herein incorporated by reference in its entirety to provide continuity of disclosure.

### BACKGROUND OF THE INVENTION

The present invention relates to thermoelectric lighting devices. More specifically, the present invention provides a thermoelectric lamp for illuminating a space, such as, a room. The thermoelectric lamp utilizes a thermoelectric generator to convert heat flux resulting from a lit candle into electrical energy, wherein the electrical energy powers an operably connected electric motor that actuates a light source. The thermoelectric generator utilizes the Seebeck effect to convert differences in temperature, as a result of the lit candle, into electricity that powers the lamp.

During a power outage it is difficult for individuals to find the supplies they need in the dark. Without a proper light source, people may stumble or harm themselves while scavenging for items throughout a home. Flashlights and candles are only able to illuminate a small area of a room, making it difficult and dangerous to go about normal activities without power. Some light sources require a battery, which can die and needs to be replaced. Fire may be utilized as a light source, but is often not bright enough to illuminate the room. In order to address these concerns, the present invention provides a thermoelectric lamp which utilizes heat from a flame to power a LED light.

Devices have been disclosed in the known art that relate to thermoelectric lights. These include devices that have been patented and published in patent application publications. These devices generally relate to thermoelectric lights that utilize heat from the sun or ground to generate electricity. One device was designed for specific use in space, whereby thermoelectric energy from the sun produces electrical power for a space mission. Another device utilizes a heat gradient from the ground surface to generate electricity to power a road surface light. Another device coupled a thermoelectric generator to a light emitting diode (LED), wherein the generator utilized the heat generated from the LED itself and converted it into usable energy such that the efficiency of the LED was increased.

These known art devices have several known drawbacks. Many of these devices utilize solar energy or heat generated from the ground to generate electricity. These devices fail to utilize a nearby flame as a heat source to generate thermoelectric energy. Further, many of these devices lack portability and require the sun to be utilized as the heat source. Some of these devices fail to include an electric motor that is operably connected to the thermoelectric generator that powers the light source. Lastly, these devices fail to include a mirror member configured to redirect light generated from the light source.

In light of the devices disclosed in the known art, it is submitted that the present invention substantially diverges in design elements from the known art and consequently it is clear that there is a need in the art for an improvement to existing thermoelectric lighting devices. In this regard the instant invention substantially fulfills these needs.

### SUMMARY OF THE INVENTION

In view of the foregoing disadvantages inherent in the known types of thermoelectric lights now present in the known art, the present invention provides a new thermoelectric lamp wherein the same can be utilized for providing convenience for the user when illuminating a space.

It is therefore an object of the present invention to provide a new and improved thermoelectric lamp that has all of the advantages of the known art and none of the disadvantages.

It is another object of the present invention to provide a thermoelectric lamp comprising a first housing and a second housing. The first housing includes a panel and a sidewall forming an interior volume having an open lower end. A light source is disposed on a first surface of the panel, wherein the light source is operably connected to an electric motor affixed within the interior volume of the first housing. A thermoelectric generator is operably connected to the electric motor and disposed at the open lower end of the first housing. The second housing comprises a base and a sidewall forming an interior volume having an open upper end, wherein the open upper end removably secures to the lower open end of the first housing. The second housing includes an opening that receives a candle therethrough, wherein the thermoelectric generator is configured to covert heat flux generated from the candle into electrical energy that powers the light source.

Another object of the present invention is to provide a thermoelectric lamp, wherein the first housing includes a mirror member having a handle attached to a rear surface thereof, wherein the mirror member is slidably secure within a second aperture disposed on the panel.

Another object of the present invention is to provide a thermoelectric lamp, wherein the sidewall of the first housing includes a slot, configured to slidably receive the handle of the mirror member.

Yet another object of the present invention is to provide a thermoelectric lamp, wherein the light source comprises at least one light emitting diode (LED).

Another object of the present invention is to provide a thermoelectric lamp that may be readily fabricated from materials that permit relative economy and are commensurate with durability.

Other objects, features and advantages of the present invention will become apparent from the following detailed description taken in conjunction with the accompanying drawings.

### BRIEF DESCRIPTIONS OF THE DRAWINGS

Although the characteristic features of this invention will be particularly pointed out in the claims, the invention itself and manner in which it may be made and used may be better understood after a review of the following description, taken in connection with the accompanying drawings wherein like numeral annotations are provided throughout.

FIG. 1 shows a perspective view of the thermoelectric lamp.

FIG. 2 shows an exploded view of the thermoelectric lamp.

FIG. 3 shows a perspective view of the thermoelectric lamp, wherein the mirror member is in an extended position and the light source is actuated.

### DETAILED DESCRIPTION OF THE INVENTION

Reference is made herein to the attached drawings. Like reference numerals are used throughout the drawings to depict like or similar elements of the thermoelectric lamp. For the purposes of presenting a brief and clear description of the present invention, the preferred embodiment will be discussed as used for illuminating a dark space by using an LED light powered by thermoelectric energy generated from a lit candle. The figures are intended for representative purposes only and should not be considered to be limiting in any respect.

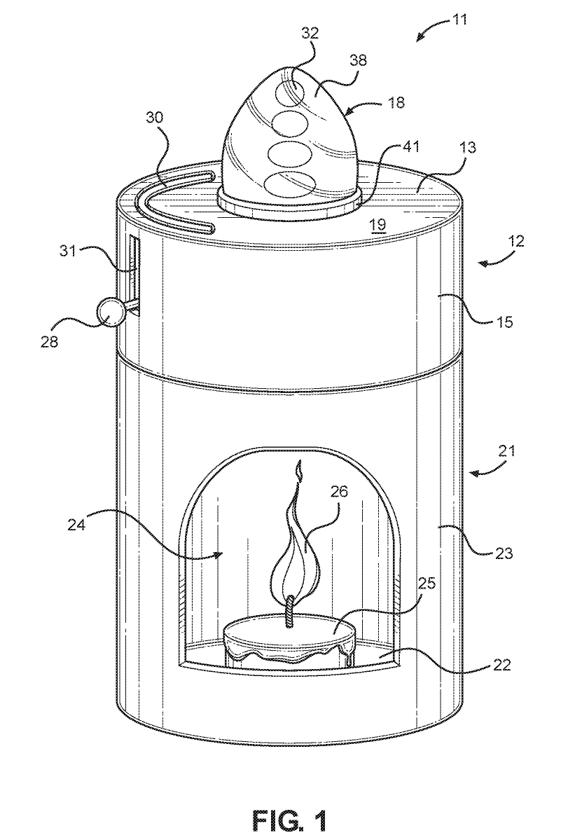

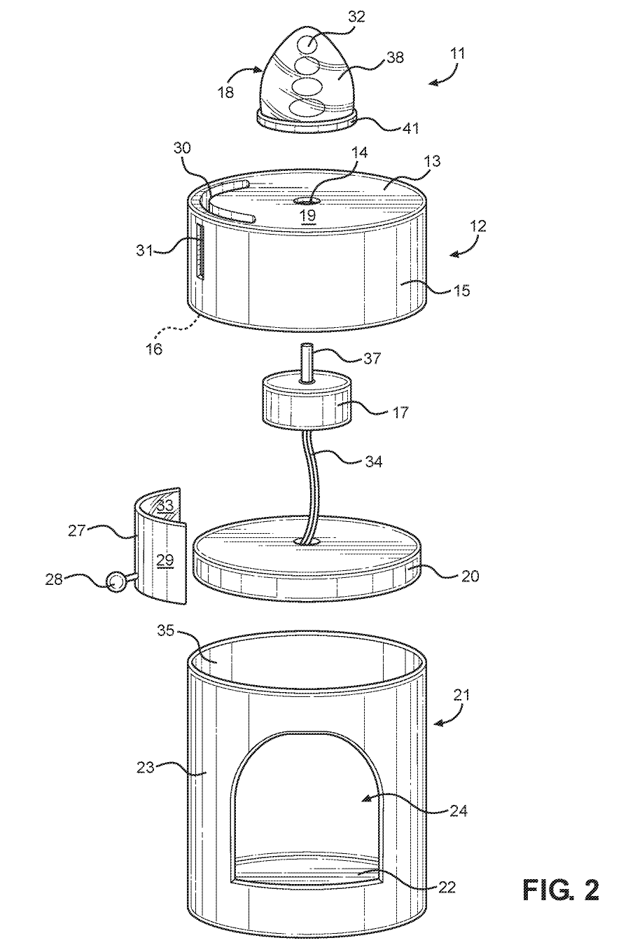

Referring now to FIGS. 1 and 2, there is shown a perspective view of an embodiment of the thermoelectric lamp and an exploded view of the thermoelectric lamp, respectively. The thermoelectric lamp 11 comprises a first housing 12 that removably secures to a second housing 21. In the illustrated embodiment, both the first housing 12 and second housing 21 are cylindrical in shape. However, each housing 12, 21 may be any suitable shape, such as, rectangular or square. The first housing 12 comprises a panel 13 having a first aperture 14 and a sidewall 15 forming an interior volume having an open lower end 16. An electric motor 17 is disposed within the interior volume of the first housing 12. The first housing 12 includes a light source 18 disposed on a first surface 19 of the panel 13, wherein the light source 18 is rotatably secured to the electric motor 17 through the first aperture 14 of the panel 13. In the illustrated embodiment, the light source 18 includes a platform 41 that rotatably secures to an axle 37 of the electric motor 17. The first housing 12 further includes a thermoelectric generator 20 disposed within the interior volume of the housing. The thermoelectric generator 20, the electric motor 17, and the light source 18 are operably connected to each other.

The second housing 21 comprises a base 22 and a sidewall 23 forming an interior volume having an open upper end 35, wherein the open upper end 35 removably secures to the lower open end 16 of the first housing 12. The housings 12, 21 removably secure via any suitable fastening means, such as, a threaded fit or press fit. The second housing 21 further comprises an opening 24 configured to receive a candle 25 therethrough. In operation, a flame 26 from a lit candle 25 generates heat flux within the second housing 21. The thermoelectric generator 20 is disposed at the open lower end 16 of the first housing 12, such that the thermoelectric generator 20 receives heat generated by the candle 25 placed within the second housing 12. The resulting heat flux is converted into electrical energy by utilizing the thermoelectric generator 20. The converted electrical energy is transferred through an electrical wire 34 that powers the electric motor 17 stored within the first housing 12. The electric motor 37 is configured to rotate an axle 37 that is operably connected to the light source 18, thereby rotating the platform 41 and powering the light source 18. In one embodiment, the light source 18 comprises at least one light emitting diode (LED) 32. In the illustrated embodiment, the light source 18 comprises a plurality of LEDs 32 disposed within a cone shaped housing 38. The cone shaped housing 38 is configured to emit light in multiple directions, thereby increasing the illumination capacity of the lamp. However, in alternative embodiments, the cone shaped housing 38 may be any suitable shape capable of emitting light.

In the illustrated embodiment, the first housing 12 further includes a mirror member 27 having handle 28 attached to a rear surface 29 thereof, wherein the mirror member 27 is slidably secure within a second aperture 30 disposed on the panel 13. In the illustrated embodiment, both the mirror member 27 and the second aperture 30 have a curved shaped. The curved shape allows the mirror member 27 to redirect light rays emanating from the light source 18 by reflecting the light off a mirrored surface 33 in a specific direction. However, in alternative embodiments, the mirror member 27 and the second aperture 30 may be any suitable shape capable of redirecting light. This configuration allows a user to redirect light in a specific direction, in order to further illuminate a specific area. The sidewall 15 of the first housing 12 includes a slot 31 that is configured to slidably receive the handle 28 of the mirror member 27, such that the mirror member can be placed in a retracted position and an extended position.

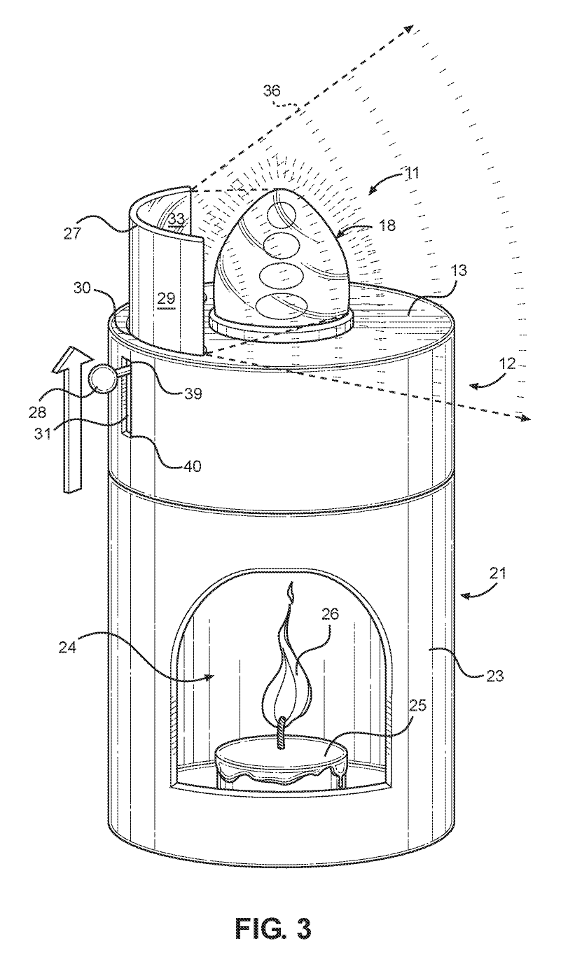

Referring now to FIG. 3, there is shown a perspective view of the thermoelectric lamp, wherein the mirror member is in an extended position and the light source is actuated. The handle 28 is affixed to the rear surface 29 of the mirror member 27, wherein the handle 28 is configured to slide along the slot 31. When the handle 28 is placed at a first end 39 of the slot 31, the mirror member 27 is in an extended position. In this configuration the mirror member 27 is received through the second aperture 30 of the panel 13, wherein the mirror member fully extends outwardly from the panel 13. When the handle 28 is placed at a second end 40 of the slot, the mirror member 27 is in a retracted position, such that the mirror member 27 retracts into the interior volume of the housing 12 wherein a top edge of the mirror member rests flush with the surface of the top panel 13.

In the illustrated embodiment, the candle 25 is placed within the second housing 21. The candle 25 can be lit through the opening 24 to produce a flame 26 in order to generate heat flux. The heat flux is converted to electric energy by the thermoelectric generator to power the electric motor that actuates the light source 18. Once actuated, the light source 18 produces light rays 36 that radiate therefrom. The light rays 36 will radiate outwardly in multiple directions when the mirror member 27 is in a retracted position, thereby illuminating a large area, such as a room. When in the extended position, the mirror member 27 is exposed above the surface of the panel 13, wherein it reflects the light rays 36 of the light source 18 off the mirrored surface 33 thereof. The mirror member 27 allows a user to redirect light rays 36 from the light source 18 in a specific direction to further illuminate a specific area within the room.

It is therefore submitted that the instant invention has been shown and described in what is considered to be the most practical and preferred embodiments. It is recognized, however, that departures may be made within the scope of the invention and that obvious modifications will occur to a person skilled in the art. With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

I claim:

1) A thermoelectric lamp, comprising:
a first housing comprising:
a panel having a first aperture;
a sidewall forming an interior volume having an open lower end;
an electric motor disposed within the interior volume;
a light source disposed on a first surface of the panel, wherein the light source is rotatably secure to the electric motor through the first aperture;
a thermoelectric generator disposed within the interior volume, wherein the thermoelectric generator, the electric motor, and the light source are operably connected to each other;
a second housing comprising:
a base;
a sidewall forming an interior volume having an open upper end, wherein the open upper end removably secures to the lower open end of the first housing; and
an opening configured to receive a candle therethrough.

2) The thermoelectric lamp of claim 1, wherein the first housing includes a mirror member having a handle attached to a rear surface thereof, wherein the mirror member is slidably secure within a second aperture disposed on the panel;

3) The thermoelectric lamp of claim 2, wherein the sidewall of the first housing includes a slot, configured to slidably receive the handle of the mirror member.

4) The thermoelectric lamp of claim 1, wherein the light source comprises at least one light emitting diode (LED).

5) The thermoelectric lamp of claim 1, wherein the first housing and the second housing are cylindrical in shape.

6) The thermoelectric lamp of claim 1, wherein the light source comprises a cone shaped housing.

7) The thermoelectric lamp of claim 1, wherein the thermoelectric generator is mounted at the open lower end of the first housing, such that the thermoelectric generator is configured to receive heat generated from a lit candle placed within the second housing.
